(19) United States
(12) Patent Application Publication
(10) Pub. No.: US 2005/0139975 A1
(43) Pub. Date: Jun. 30, 2005

(54) Tension resistant structure

(76) Inventor: Jung Han Kim, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 11/023,926

(22) Filed: Dec. 28, 2004

(30) Foreign Application Priority Data
Dec. 30, 2003 (KR) 2003-100220

(51) Int. Cl. H01L 23/02

(52) U.S. Cl. 257/678

(57) ABSTRACT

Disclosed is a tension resistant structure. The tension resistant structure includes a TCP/COF (tape carrier package/chip on film) tape having first and second sprocket holes formed at upper and lower ends of the TCP/COF tape while forming an interval of a predetermined pitch therebetween and supporters provided at both sides of the first and second sprocket holes of the TCP/COF tape so as to absorb tension being applied to the TCP/COF tape. The supporters are installed at both sides of the TCP/COF tape, so the TCP/COF tape made from Upilex/Kapton is prevented from being cut off while the TCP/COF tape is being fed or retrieved.

### BACKGROUND OF THE INVENTION

1. Field of the invention

The present invention relates to a tension resistant structure, and more particularly to a tension resistant structure capable of absorbing tension being applied to a TCP/COF (tape carrier package/chip on film) tape by using a supporter.

2. Description of the Prior Art

FIG. 1 shows a structure of a conventional TCP/COF tape.

When fabricating an LCD, a punching process is carried out for the TCP/COF tape so as to provisionally press-bond the TCP/COF tape to each pattern. After the punching process has been completed, remaining film tapes 104 formed with sprocket holes 102 are wound around a film retrieving section. However, since the conventional TCP/COF tape employs a polyimide film tape made from Upilex/Kapton, the film tapes 104 may be cut off due to tension applied to the film tapes 104 when the film tapes 104 are wound around the film retrieving section.

### SUMMARY OF THE INVENTION

Accordingly, the present invention has been made to solve the above-mentioned problems occurring in the prior art, and an object of the present invention is to provide a tension resistant structure capable of preventing a TCP/COF tape made from Upilex/Kapton from being cut off by reinforcing the TCP/COF tape using supporters installed at both sides of a sprocket hole.

In order to accomplish the above object, according to the present invention, there is provided a tension resistant structure comprising: a TCP/COF (tape carrier package/chip on film) tape having first and second sprocket holes formed at upper and lower ends of the TCP/COF tape while forming an interval of a predetermined pitch therebetween; and supporters provided at both sides of the first and second sprocket holes of the TCP/COF tape so as to absorb tension applied to the TCP/COF tape.

According to the preferred embodiment of the present invention, the supporters are fabricated by using one selected from the group consisting of tin, aluminum, glass cloth, glass fiber, Teflon, polyethylene, polyester, cotton, nylon, thermoplastic resin, lead, copper, iron, urethane, polyurethane, silicon, polyimide, polystyrene, polycarbonate, and acrylonitrile butadiene styrene resin.

According to the preferred embodiment of the present invention, the TCP/COF tape is fabricated the steps of forming tin-based patterns on a polyimide film tape made from Upilex/Kapton as input and output patterns, mounting a drive IC on the polyimide film tape, and winding the polyimide film tape around a reel.

According to the preferred embodiment of the present invention, cutting lines are formed in the TCP/COF tape in such a manner that remaining TCP/COF tape is be retrieved into the reel after a desired amount of the TCP/COF tape has been used.

### BRIEF DESCRIPTION OF THE DRAWINGS

The above and other objects, features and advantages of the present invention will be more apparent from the following detailed description taken in conjunction with the accompanying drawings, in which:

FIG. 1 is a view illustrating a structure of a conventional TCP/COF tape;

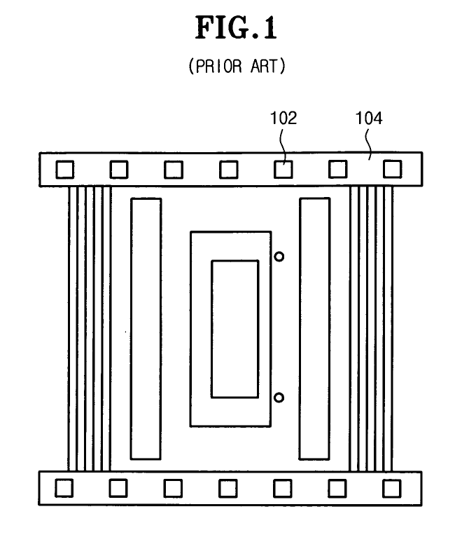

FIG. 2 is a view illustrating a tension resistant structure according to the preferred embodiment of the present invention;

FIG. 3 is a view illustrating a TCP/COF tape used for the present invention before the TCP/COF tape is subject to a punching process; and

FIG. 4 is a view illustrating a TCP/COF tape used for the present invention after a punching process has been carried out for the TCP/COF tape.

### DETAILED DESCRIPTION OF THE PREFERRED EMBODIMENTS

Hereinafter, a tension resistant structure according to the present invention will be described with reference to accompanying drawings.

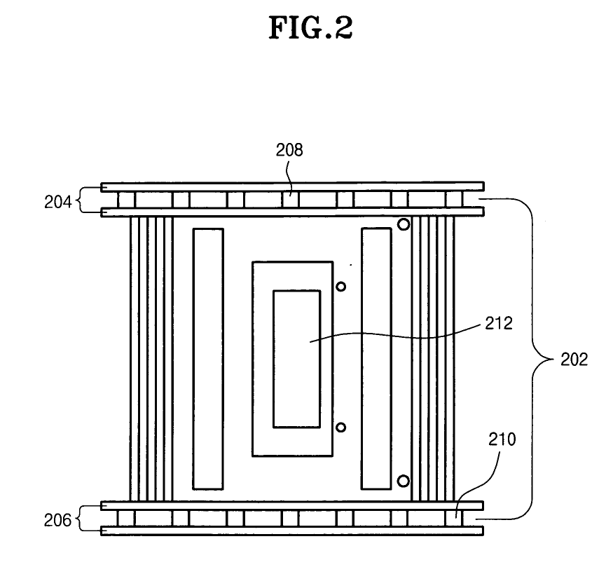

FIG. 2 is a view illustrating the tension resistant structure according to the preferred embodiment of the present invention.

As shown in FIG. 2, the tension resistant structure of the present invention includes a TCP/COF tape 202, a first supporter 204 and a second supporter 206.

The TCP/COF tape 202 is formed with first and second sprocket holes 208 and 210, which are formed at upper and lower ends of the TCP/COF tape 202 while forming an interval at a predetermined pitch therebetween. The first supporter 204 is provided at both sides of the first sprocket holes 208 of the TCP/COF tape 202 in order to absorb tension being applied to the first sprocket holes 208 of the TCP/COF tape 202.

The second supporter 206 is provided at both sides of the second sprocket holes 210 of the TCP/COF tape 202 in order to absorb tension being applied to the second sprocket holes 210 of the TCP/COF tape 202.

According to the preferred embodiment of the present invention, the first and second supporters 204 and 206 are fabricated by using one selected from the group consisting of tin, aluminum, glass cloth, glass fiber, Teflon, polyethylene, polyester, cotton, nylon, thermoplastic resin, lead, copper, iron, urethane, polyurethane, silicon, polyimide, polystyrene, polycarbonate, and acrylonitrile butadiene styrene resin.

In order to fabricate the TCP/COF tape 202, tin-based patterns are formed on a polyimide film tape made from Upilex/Kapton as input and output patterns and a drive IC 212 is mounted on the polyimide film tape. In this state the polyimide film tape is wound around a reel. Cutting lines are formed in the TCP/COF tape 202 in such a manner that remaining TCP/COF tape 202 can be retrieved into the reel after a desired amount of the TCP/COF tape 202 has been used.

That is, after the cutting line has been punched by means of a puncher, the remaining TCP/COF tape 202 is rewound around the reel. When feeding/retrieving the TCP/COF tape 202 through the reel, a sprocket wheel of the reel is engaged with the first and second sprocket holes 208 and 210 formed in the TCP/COF tape 202.

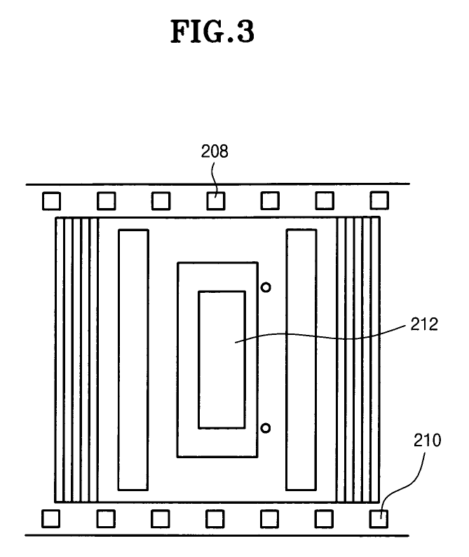

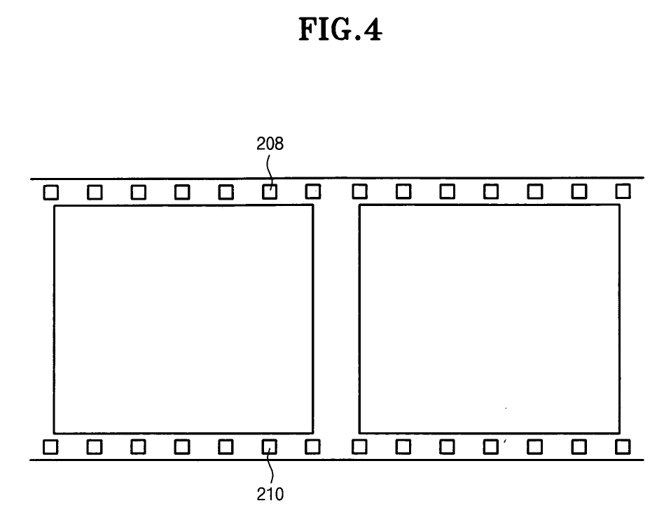

FIG. 3 is a view illustrating a TCP/COF tape used for the present invention before the TCP/COF tape is subject to a punching process and FIG. 4 is a view illustrating the TCP/COF tape used for the present invention after the punching process has been carried out for the TCP/COF tape.

One sprocket wheel is provided in a feeding reel and a retrieving reel, respectively. The feeding reel is driven by means of a motor so as to constantly feed the TCP/COF tape, and the retrieving reel is driven by an AC motor so as to constantly retrieve the TCP/COF tape.

At this time, if tension is unevenly applied to the feeding reel and the retrieving reel during the punching process, or if a great amount of the TCP/COF tape is wound around the feeding reel or the retrieving reel, a rotational speed of the feeding reel or the retrieving reel is irregularly changed so that tension of the TCP/COF tape occurs unevenly. Accordingly, after the punching process for the cutting line has been finished, the TCP/COF tape may be cut off due the tension applied to the TCP/COF tape.

The polyimide film tape made from Upilex/Kapton is formed at both longitudinal sides of the sprocket holes with margins having a size of about 1 mm.

According to the present invention, tension patterns are designed on the margins and supporters are installed in the tension patterns so as to absorb tension being applied to the TCP/COF tape, thereby preventing the TCP/COF tape from being cut off when feeding or retrieving the TCP/COF tape.

As described above, when the TCP/COF tape including the sprocket holes is rewound around the retrieving reel after the punching process for the TCP/COF tape has been finished, the conventional polyimide film tape made from Upilex/Kapton may be cut off due to tension applied thereto. However, according to the present invention, tension patterns are formed at both sides of the sprocket holes and the supporters are installed in the tension patterns so as to absorb the tension applied to the TCP/COF tape, so the TCP/COF tape can be prevented from being cut off while the TCP/COF tape is being fed or retrieved.

The tension resistant structure according to the present invention may be applicable not only for LCDs employing the TCP/COF tape, but also for communication appliances and toys.

In addition, the tension resistant structure according to the present invention is applicable for optical devices, imaging devices and surface mounting devices in order to reinforce films having sprocket holes used for the above devices.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A tension resistant structure comprising:
a TCP/COF (tape carrier package/chip on film) tape having first and second sprocket holes formed at upper and lower ends of the TCP/COF tape while forming an interval at a predetermined pitch therebetween; and
supporters provided at both sides of the first and second sprocket holes of the TCP/COF tape so as to absorb tension applied to the TCP/COF tape.

2. The tension resistant structure as claimed in claim 1, wherein the supporters are fabricated by using one selected from the group consisting of tin, aluminum, glass cloth, glass fiber, Teflon, polyethylene, polyester, cotton, nylon, thermoplastic resin, lead, copper, iron, urethane, polyurethane, silicon, polyimide, polystyrene, polycarbonate, and acrylonitrile butadiene styrene resin.

3. The tension resistant structure as claimed in claim 1, wherein the TCP/COF tape is fabricated the steps of forming tin-based patterns on a polyimide film tape made from Upilex/Kapton as input and output patterns, mounting a drive IC on the polyimide film tape, and winding the polyimide film tape around a reel.

4. The tension resistant structure as claimed in claim 3, wherein cutting lines are formed in the TCP/COF tape in such a manner that remaining TCP/COF tape is be retrieved into the reel after a desired amount of the TCP/COF tape has been used.
